(19) United States
(12) Patent Application Publication
(10) Pub. No.: US 2025/0105108 A1
(43) Pub. Date: Mar. 27, 2025

(54) SEMICONDUCTOR DEVICE COMPRISING A SEMICONDUCTOR DIE SANDWICHED BETWEEN TWO LEADFRAMES AND A METHOD FOR FABRICATING THE SAME

(71) Applicant: Infineon Technologies AG, Neubiberg (DE)

(72) Inventor: Stefan MACHEINER, Kissing (DE)

(73) Assignee: Infineon Technologies AG, Neubiberg (DE)

(21) Appl. No.: 18/794,460

(22) Filed: Aug. 5, 2024

(30) Foreign Application Priority Data
Sep. 26, 2023 (DE) 10 2023 126 006.5

(51) Int. Cl. H01L 23/495; H01L 21/48; H01L 21/56; H01L 23/00

(52) U.S. Cl. CPC H01L 23/49562; H01L 21/4842; H01L 21/565; H01L 23/49513; H01L 24/96; H01L 24/97; H01L 24/32; H01L 2224/32245; H01L 2224/96; H01L 2224/97; H01L 2924/1815

(57) ABSTRACT

A semiconductor device is disclosed. In one example, the semiconductor device includes a leadframe for flip chip attaching a semiconductor die thereon that comprises a rectangular area segmented into individual pads. The individual pads comprise a first pad, a second pad, and a third pad, wherein the first pad is larger than the second pad and larger than the third pad. The second pad is located in a first corner area of the rectangular area and the third pad is located in a second corner area of the rectangular area. The second corner area is located diagonally opposite to the first corner area.

### CROSS-REFERENCE TO RELATED APPLICATION

This Utility Patent Application claims priority to German Patent Application No. 10 2023 126 006.5 filed Sep. 26, 2023, which is incorporated herein by reference.

### TECHNICAL FIELD

The present disclosure is related to a semiconductor device and a method for fabricating the same.

### BACKGROUND

Power semiconductor packages include a power semiconductor die embedded in a mold compound. One big issue in semiconductor power packages is the dissipation of excessive heat generated by the semiconductor power die in operation. The heat generated by the semiconductor power die needs to be efficiently dissipated out of the semiconductor package into the environment. In case of a leadless surface-mounted semiconductor package the heat can be dissipated via the bottom-side PCB. However, additional top side cooling is a major trend in the fabrication of semiconductor power packages. In this case a metallic contact which is connected with the semiconductor die is exposed to the outside thus allowing a heatsink to be connected to the metallic contact.

However, surface-mounted semiconductor packages have the general disadvantage that in the case of mechanical stresses, for example due to different coefficients of thermal expansion, no compensation mechanism can be provided due to the lack of flexibility of the metal contacts lying on the surface of the PCB resulting in a lack of board level reliability (BLR).

### SUMMARY

A first aspect of the present disclosure is related to a semiconductor device comprising a first leadframe comprising a first die pad and one or more first leads formed integral with the first die pad and extending outward from the first die pad in a first direction, a second leadframe comprising a second die pad and one or more second leads formed integral with the second die pad and extending outward from the second die pad in a second direction different than the first direction, a semiconductor die disposed between the first die pad and the second die pad, and an encapsulant embedding the semiconductor die, wherein the first leads and the second leads are disposed outside the encapsulant.

Due to the fact that the first and second leads are disposed outside the encapsulant after mounting the semiconductor device onto a PCB the leads are more flexible to absorb any kind of mechanical stress between the semiconductor device and the PCB, which can increase board level reliability.

According to an embodiment of the semiconductor device of the first aspect, the second die pad of the second leadframe is at least partially exposed to the outside so that a heat sink can be mounted onto a surface of the second die pad remote from the semiconductor die. Mounting of the heatsink can be done either in the fabrication process of the semiconductor device or on the customer's side. The second die pad can in particular be fully exposed to the outside. Otherwise it can be partially exposed and in the remaining part the encapsulant is exposed to the outside.

According to an embodiment of the semiconductor device of the first aspect, the first die pad is disposed in a first plane, and the second die pad is disposed in a second plane, and the first leads extend outside the encapsulant from the first plane to a third plane, and the second leads extend outside the encapsulant from the second plane to the third plane.

According to an embodiment of the semiconductor device of the first aspect, the encapsulant comprises a lower surface which faces the PCB after mounting the semiconductor device onto a PCB. In some embodiments, this lower surface can lie in the third plane so that the encapsulant will be in contact with the surface of the PCB after mounting the semiconductor device onto a PCB thereby allowing heat dissipation through the PCB when operating the semiconductor device. Otherwise the lower surface of the encapsulant can be disposed above the third plane in which case no bottom side cooling is possible.

According to an embodiment of the semiconductor device of the first aspect, the first leads are bent from the first die pad by a first angle, and the second leads are bent from the second die pad by a second angle. According to a further example thereof, the second angle is different from the first angle. According to a further example thereof, none of the first and second angles is zero.

According to an embodiment of the semiconductor device of the first aspect, the semiconductor die is a semiconductor transistor die. In particular, the semiconductor die can be one or more of a vertical semiconductor transistor die, a semiconductor power transistor die, an IGBT die, a MOSFET die, a CoolMOS die, a wide band gap semiconductor transistor die, in particular a SiC transistor die.

According to an embodiment of the semiconductor device of the first aspect, the semiconductor transistor die comprises a first main face and a second main face opposite to the first main face, and a source pad disposed on the first main face and a drain pad disposed on the second main face. According to one embodiment, the drain pad would be connected to the first leadframe, and the source pad would be connected to the second leadframe. According to a further example thereof, the semiconductor device further comprises a gate pad disposed on the first main face and possibly also a source/sense pad also disposed on the first main face.

A second aspect of the present disclosure is related to a method for fabricating a semiconductor device, the method comprising providing a first leadframe, providing a semiconductor die comprising a first main face and a second main face opposite to the first main face, connecting a first main face of the semiconductor die with a first portion of the first leadframe, providing a second leadframe, connecting a first portion of the second leadframe to the second main face of the semiconductor die, applying an encapsulant to the semiconductor die and to the first portions of the first and second leadframes so that second portions of the first and second leadframes are disposed outside the encapsulant.

When the method is performed as described above, the first portions of the first and second leadframes become the die pads and the second portions of the first and second leadframes become the leads of the semiconductor device according to the first aspect.

The method according to the second aspect can be carried out in different ways with respect to the sequence of the method steps. Common to all embodiments is that the semiconductor device to be fabricated has first portions of the leadframes serving as the die pads and second portions bent from the first portions serving as the leads. In a very practicable way of fabricating, a leadframe supplier pre-bends the leadframes and then sends the pre-bent leadframes to a customer for semiconductor package assembly. In general, the method may be carried out so that already at the initial provision of the leadframes the second portions are partially or completely bent from the first portions. Finally, the method can be carried out so that the bending of the second portions from the first portions is carried out completely after the encapsulant has been attached.

According to an embodiment of the method of the second aspect, the second portions of the first leadframe are bent by a first angle and the second portions of the second leadframe are bent by a second angle. According to a further example thereof, the second angle is different from the first angle.

According to an embodiment of the method of the second aspect, the method is carried out such that a surface of the first portion of the second leadframe remote from the semiconductor die is exposed to the outside.

According to an embodiment of the method of the second aspect, two semiconductor devices are fabricated in parallel by connecting two semiconductor dies to the first leadframe, providing two second leadframes, connecting each one of the two second leadframes with one of the semiconductor dies, applying two encapsulants to each one of the semiconductor dies and to first portions of the first and second leadframes, and singulating into two separate semiconductor devices.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 shows a cross-sectional view of an example of a semiconductor device according to the first aspect.

FIG. 2 comprises FIGS. 2A to 2C and shows cross-sectional views of other examples of semiconductor devices according to the first aspect.

FIG. 3 comprises FIG. 3A to 3C and shows cross-sectional views to illustrate a method for fabricating the example of a semiconductor device as shown in FIG. 1.

FIG. 4 comprises FIG. 4A to 4C and shows cross-sectional views to illustrate a method for fabricating another example of a semiconductor device.

FIG. 5 comprises FIG. 5A to 5E and shows cross-sectional views to illustrate a method for fabricating two or more semiconductor devices in a parallel process.

### DETAILED DESCRIPTION

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

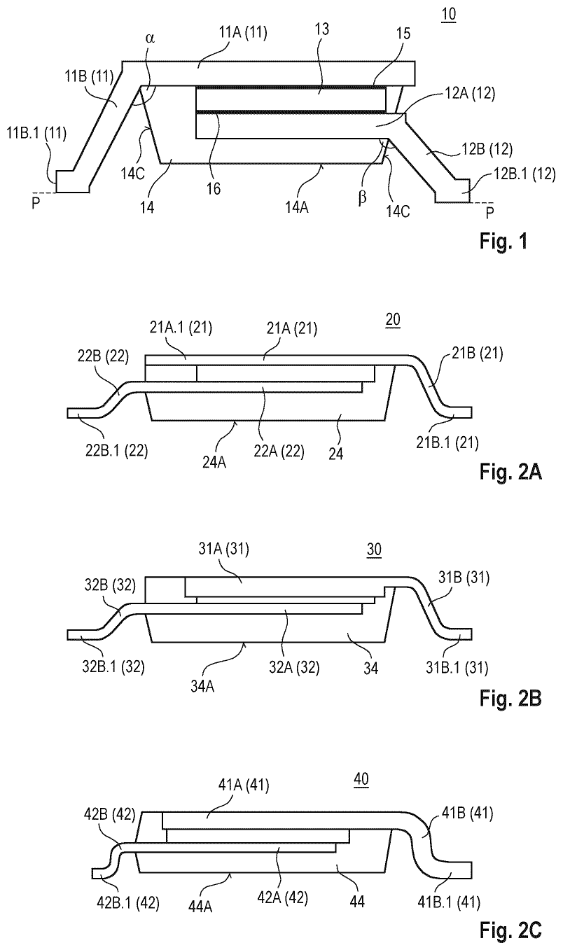

FIG. 1 shows a cross-sectional view of an example of a semiconductor device according to the first aspect.

In particular, FIG. 1 shows a semiconductor device 10 comprising a first leadframe 11 comprising a first die pad 11A and one or more first leads 11B formed integral with the first die pad 11A and extending outward from the first die pad 11A in a first direction, a second leadframe 12 comprising a second die pad 12A and one or more second leads 12B formed integral with the second die pad 12A and extending outward from the second die pad 12A in a second direction different than the first direction, a semiconductor die 13 disposed between the first die pad 11A and the second die pad 12A, and an encapsulant 14 embedding the semiconductor die 13, wherein the first leads 11B and the second leads 12B are essentially or for the most part disposed outside the encapsulant 14.

The semiconductor die 13 can be connected with its upper main face to the first die pad 11A by means of a first conductive layer 15, and the semiconductor die 13 can be connected with its lower main face to the upper main face of the second die pad 12A by means of a second conductive layer 16. The first and second conductive layers 15 and 16 may, for example, comprise soldered layers or sintered layers.

The first leads 11B and the second leads 12B both have end attachment members 11B.1 and 12B.1, which have horizontal bottom surfaces lying within a common horizontal plane P-P and by means of which bottom surfaces the semiconductor device 10 can be attached to a substrate such as a PCB. In general, different types of lead shapes can be used like, for example, gull-wing, type, J-lead type, C-lead type or through-hole type.

As shown in the example of a semiconductor device 10 of FIG. 1, the encapsulant 14 may comprise a lower horizontal surface 14A and chamfered side walls 14B disposed between the first die pad 11A and the lower horizontal surface 14A. As further shown in the example of FIG. 1, the lower horizontal surface 14A of the encapsulant 14 is located above the horizontal plane P-P. Other embodiments will be presented further below in which the lower horizontal plane of the encapsulant is located coplanar with the horizontal plane P-P.

As a result, in the example shown in FIG. 1, when the semiconductor device 10 is mounted on a substrate such as a PCB, the semiconductor device 10 comes into contact with the PCB only via its first and second conductors 11B and 12B, but not with the encapsulant 14. In the example shown, heat dissipation occurs mostly through the top side and to the bottom side only via the leads.

As also will be shown later, the first leads 11B and the second leads 12B can be created by bending first corresponding portions from the first die pad 11A and second corresponding portions from the second die pad 12A. As can be seen in FIG. 1, there is a first angle α between the first leads 11B and the first die pad 11A and a second angle β between the second leads 11B and the second die pad 11A.

The example shown in FIG. 1 is further characterized by the fact that the first pad 11A is completely exposed to the outside. As other examples will show, it is also possible that the first pad is only partially exposed to the outside. In any case, this provides the possibility of attaching an external heat sink to enable top side cooling during operation. The first leads 11B are bent from the first die pad 11A by a first angle, and the second leads 12B are bent from the second die pad 12A by a second angle.

Furthermore the semiconductor die 13 can be a semiconductor transistor die 13 and in particular one or more of a vertical semiconductor transistor die, a semiconductor power transistor die, an IGBT die, a MOSFET die, a CoolMOS die, and a wide band gap semiconductor transistor die, in particular a SiC transistor die.

More specifically, the semiconductor transistor die 13 may comprise a first main face and a second main face opposite to the first main face, and a source pad disposed on the first main face and a drain pad disposed on the second main face, and possibly also a gate pad and a source/sense pad both disposed on the first main face.

The encapsulant 14 may be comprised of a conventional mold compound like, for example, a resin material, in particular an epoxy resin material. Moreover, the encapsulant 14 can be made of a thermally conductive material to allow efficient heat dissipation to external application heat sinks. The material of the encapsulant 14 can, in particular, comprise a resin like an epoxy resin material filled with particles like, for example, SiO or other ceramic particles, or thermally conductive particles like, for examples, Al₂O₃, BN, AlN, Si₃N₄, diamond, or any other thermally conductive particles.

FIG. 2 comprises FIGS. 2A to 2C and shows cross-sectional views of other examples of semiconductor devices according to the first aspect.

FIG. 2A shows an example of a semiconductor device 20 comprising a first leadframe 21 comprising a first die pad 21A and one or more first leads 21B formed integral with the first die pad 21A and extending outward from the first die pad 21A in a first direction, a second leadframe 22 comprising a second die pad 22A and one or more second leads 22B formed integral with the second die pad 22A and extending outward from the second die pad 22A in a second direction different than the first direction, a semiconductor die 23 disposed between the first die pad 21A and the second die pad 22A, and an encapsulant 24 embedding the semiconductor die 23, wherein the first leads 21B and the second leads 22B are essentially or for the most part disposed outside the encapsulant 24.

As a difference to the example as shown in FIG. 1, a lower main face 24A of the encapsulant 24 is coplanar with the plane P-P (see FIG. 1) and thus with the lower main faces of the end attachment members 21B.1 and 22B.1 of the first and second leads 21B and 22B. As a further difference, the first die pad 21A is connected with an extended metallic connector 21A.1 disposed on the encapsulant 24. In a further embodiment, 21A and 21A.1 can be made of an integral piece of metal. Due to the process, it may happen that after encapsulation a surface area of the encapsulant laterally next to the first pad 21A is exposed to the outside. If this is not desired, this surface area can be subsequently removed and replaced by the metallic connector 21A.1, which can be deposited by electroplating, for example.

With the semiconductor device 20 shown in FIG. 2A, both down side cooling and top side cooling for heat dissipation are possible during operation.

FIG. 2B shows an example of a semiconductor device 30 comprising a first leadframe 31 comprising a first die pad 31A and one or more first leads 31B formed integral with the first die pad 31A and extending outward from the first die pad 31A in a first direction, a second leadframe 32 comprising a second die pad 32A and one or more second leads 32B formed integral with the second die pad 32A and extending outward from the second die pad 32A in a second direction different than the first direction, a semiconductor die 33 disposed between the first die pad 31A and the second die pad 32A, and an encapsulant 34 embedding the semiconductor die 33, wherein the first leads 31B and the second leads 32B are essentially or for the most part disposed outside the encapsulant 34.

As a difference to the example as shown in FIG. 1, a lower main face of the encapsulant 34 is coplanar with the plane P-P (see FIG. 1) and thus with the lower main faces of the end attachment members 31B.1 and 32B.1 of the first and second leads 31B and 32B. As a further difference, a surface area of the encapsulant 34 laterally next to the first pad 31A is exposed to the outside. As a further difference, a part of the die pad 31A comprises a greater thickness than the leads 31B. This part of the die pad 31A completely covers the semiconductor die 33. The first leadframe 31 may thus comprise a dual-gauge leadframe.

In general, leadframes can be single gauge leadframes having relatively low thickness or dual gauge leadframes having relatively high thickness. In the present case the first and second leadframes can be both single gauge leadframes having the same low thickness or dual gauge leadframes having the same high thickness. Otherwise the first and second leadframes have different thickness, in particular one of them being a single gauge leadframe and the other one a dual gauge leadframe.

With the semiconductor device 30 shown in FIG. 2B, both down side cooling and top side cooling for heat dissipation are possible during operation while down side cooling also occurring via the encapsulant and not only via the leads.

FIG. 2C shows an example of a semiconductor device 40 comprising a first leadframe 41 comprising a first die pad 41A and one or more first leads 41B formed integral with the first die pad 41A and extending outward from the first die pad 41A in a first direction, a second leadframe 42 comprising a second die pad 42A and one or more second leads 42B formed integral with the second die pad 42A and extending outward from the second die pad 42A in a second direction different than the first direction, a semiconductor die 43 disposed between the first die pad 41A and the second die pad 42A, and an encapsulant 44 embedding the semiconductor die 43, wherein the first leads 41B and the second leads 42B are essentially or for the most part disposed outside the encapsulant 44.

As a difference to the example as shown in FIG. 1, a lower main face of the encapsulant 44 is coplanar with the plane P-P (see FIG. 1) and thus with the lower main faces of the end attachment members 41B.1 and 42B.1 of the first and second leads 41B and 42B. As a further difference, a surface area of the encapsulant 44 laterally next to the first pad 41A is exposed to the outside. As a further difference, the first die pad 41A and the first leads 41B comprise over their whole length a greater thickness than the second die pad 42A and the second leads 42B.

With the semiconductor device 40 shown in FIG. 2C, both down side cooling and top side cooling for heat dissipation are possible during operation.

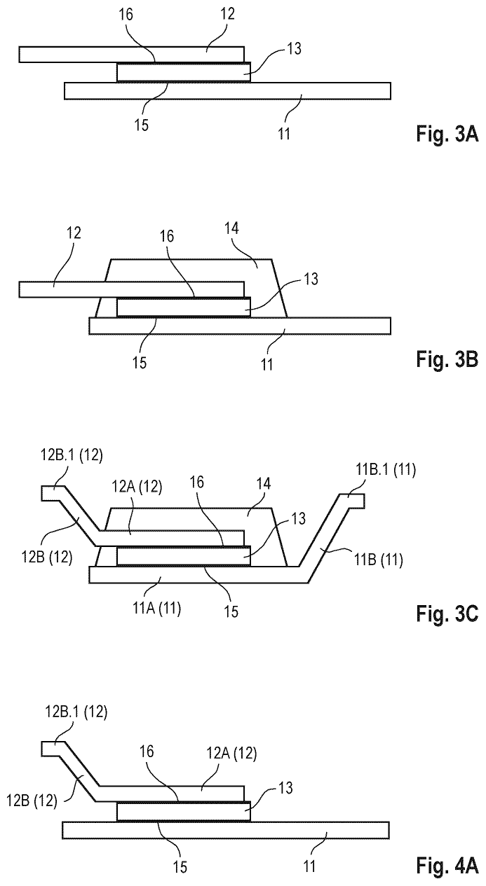

FIG. 3 comprises FIG. 3A to 3C and shows cross-sectional views to illustrate a method for fabricating the example of the semiconductor device as shown in FIG. 1.

FIG. 3A shows providing a first leadframe 11 in the form of a flat sheet of a Cu metal. A semiconductor die 13 comprises a first main surface and a second main surface opposite to the first main surface and is connected with its first main surface to a first portion of an upper surface of the first leadframe by means of a first conductive layer 15. A second leadframe 12 is provided which likewise has the form of a flat sheet of a Cu metal. The second leadframe 12 is connected with a first portion thereof to the second main face of the semiconductor die 13 by means of a second conductive layer 16. The first and second conductive layers 15 and 16 can be soldered or sintered layers 16.

FIG. 3B shows applying an encapsulant 14 to the semiconductor die 13 and to the first portions of the first and second leadframes 11 and 12. As already mentioned before, the encapsulant 14 may be comprised of a conventional mold compound like, for example, a resin material, in particular an epoxy resin material, possibly filled with thermally conductive particles. The encapsulant 14 is applied so that it only embeds the semiconductor die 13 and first portions of the first and second leadframes 11 and 12 and leaves second portions free. Concerning the application process, the encapsulant 14 can be applied by transfer molding or compression molding.

FIG. 3C shows bending second portions 11B and 12B of the first and second leadframes 11 and 12 so that outer ends of the second portions 11B and 12B come to lie in a plane which is parallel to the first portions 11A and 12A of the first and second leadframes 11 and 12. In this way the first portions 11A and 12A of the leadframes 11 and 12 become the die pads 11A and 12A and the second portions 11B and 12B become the leads 11B and 12B. The end attachment members 11B.1 and 12B.1 can be formed by appropriate bending of end portions of the first and second leads 21B. As mentioned before, the bending as shown in FIG. 3C can also be done before the molding. Also possible is that only one of the leads 11B or 12B are bent, thereafter the molding is performed, and thereafter the other one of the leads 11B or 12B are being bent.

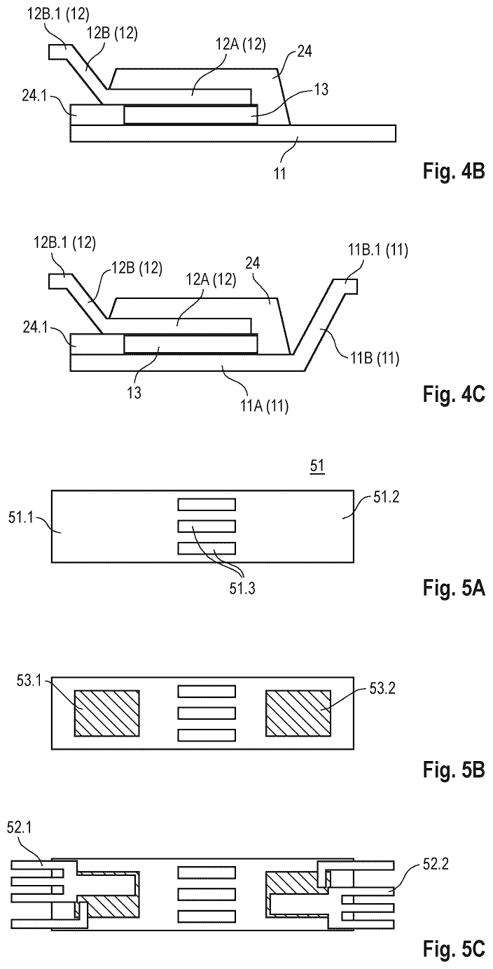

FIG. 4 comprises FIG. 4A to 4C and shows cross-sectional views to illustrate a method for fabricating another example of a semiconductor device.

FIG. 4A is similar to FIG. 3A, so that not all the details will be repeated here. A difference to FIG. 3A is that the second leadframe 12 is provided from the beginning so that it comprises a die pad 12A and one or more leads 12B which are bent from the die pad 12A.

FIG. 4B shows applying an encapsulant 24 to the semiconductor die 13 and to the first portions of the first and second leadframes 11 and 12. The encapsulant 24 can have the same or similar properties as the encapsulant 14 of FIG. 3. The difference to the encapsulant 14 is that the encapsulant 24 is applied so that it comprises an additional portion 24.1 at one side of the semiconductor die 13. This additional area provides a more robust encapsulation and possibly also an increased high voltage endurance, i.e. strength of the semiconductor device to high electrical voltages. The device manufactured in this way is therefore particularly suitable for high-voltage applications.

FIG. 4C shows the bending of second portions 11B from the first portion 11A so that now the first portion 11A can be said to serve as die pad 11A and the second portions 11B can be said now to serve as leads 11B of the second leadframe 11.

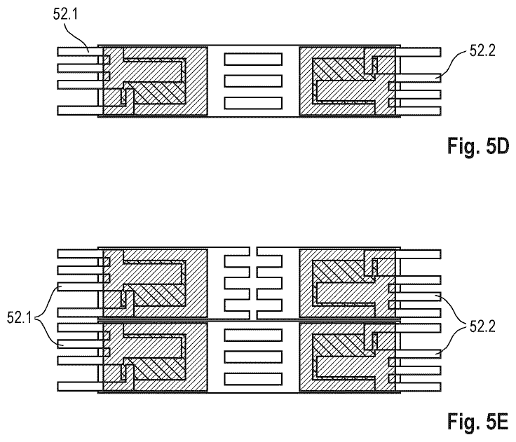

FIG. 5 comprises FIG. 5A to 5E and shows cross-sectional views to illustrate a method for fabricating two or more semiconductor devices in a parallel process.

FIG. 5A shows providing a first leadframe 51 which comprises two oppositely disposed regions 51.1 and 511.2 and a region 51.3 which is configured so that the two regions 51.1 and 51.2 can be easily separated from each other in a later step. The region 51.3 essentially comprises a number of interconnecting ridges between the regions 51.1 and 51.2, which are to serve as leads of the semiconductor devices to be manufactured after they are cut in the final process step.

FIG. 5B shows the connecting of two semiconductor dies 53.1 and 53.2 to the two regions 51.1 and 51.2 of the first leadframe 51.

FIG. 5C shows the connecting of two second leadframes 52.1 and 52.2 to upper surfaces of the two semiconductor dies 53.1 and 53.2.

FIG. 5D indicates the applying of encapsulants to the two semiconductor dies 53.1 and 53.2 and portions of the two leadframes 52.1 and 52.2. After cutting the interconnecting ridges of the region 51.3, two semiconductor devices can be obtained.

FIG. 5E indicates another solution where even 4 semiconductor devices can be obtained. Here, two assemblies as shown in FIG. 5C are placed side by side and one encapsulant is applied to each of the two upper and lower regions of the combines assembly. Subsequently, 4 semiconductor devices can be obtained by singulation.

### EXAMPLES

In the following specific examples of the present disclosure are described.

Example 1 is a semiconductor device comprising a first leadframe comprising a first die pad and one or more first leads formed integral with the first die pad and extending outward from the first die pad in a first direction, a second leadframe comprising a second die pad and one or more second leads formed integral with the second die pad and extending outward from the second die pad in a second direction different than the first direction, a semiconductor die disposed between the first die pad and the second die pad, and an encapsulant embedding the semiconductor die, wherein the first leads and the second leads are disposed outside the encapsulant.

Example 2 is the semiconductor device according to Example 1, wherein the first die pad is disposed on a first level, and the second die pad is disposed on a second level, and the first leads extend outside the encapsulant from the first level to a third level, and the second leads extend outside the encapsulant from the second level to the third level.

Example 3 is the semiconductor device according to Example 1 or 2, wherein the first die pad of the first leadframe is at least in part exposed at the top surface of the package.

Example 4 is the semiconductor device according to any one of the preceding Examples, wherein the semiconductor die is a vertical semiconductor transistor die, in particular a semiconductor power transistor die, an IGBT die, a MOSFET die, a CoolMOS die, a wide band gap semiconductor transistor die, in particular a SiC transistor die.

Example 5 is the semiconductor device according to Example 4, wherein the semiconductor transistor die comprises a first main face and a second main face opposite to the first main face, and a source pad disposed on the first main face and a drain pad disposed on the second main face.

Example 6 is the semiconductor device according to Example 5, wherein the drain pad is connected with the first die pad of the leadframe and the source pad is connected with the second die pad of the second leadframe.

Example 7 is the semiconductor device according to Example 5 or 6, further comprising a gate pad disposed on the first main face.

Example 8 is the semiconductor device according to any one of the preceding Examples, wherein the device is a leaded package, especially a gull-wing package, a J-lead package, a C-lead, or a through-hole package.

Example 9 is a method for fabricating a semiconductor device, the method comprising providing a first leadframe, providing a semiconductor die comprising a first main face and a second main face opposite to the first main face, connecting a first main face of the semiconductor die with a first portion of the first leadframe, providing a second leadframe, connecting a first portion of the second leadframe to the second main face of the semiconductor die, applying an encapsulant to the semiconductor die and to the first portions of the first and second leadframes so that second portions of the first and second leadframes are disposed outside the encapsulant.

Example 10 is the method according to Example 9, further comprising after applying the encapsulant bending at least part of the second portions of the first and second leadframes so that outer ends of the second portions come to lie in a plane which is parallel to the first portions of the first and second lead frames, or providing one or both of the first and second leadframes in the form of pre-bent leadframes.

Example 11 is the method according to Example 10, wherein the second portions of the first leadframe are bent by a first angle and the second portions of the second leadframe are bent by a second angle.

Example 12 is the method according to any one of Examples 9 to 11, wherein the method is carried out such that a surface of the first portion of the first leadframe remote from the semiconductor die is exposed at the top surface of the package.

Example 13 is the method according to any one of Examples 9 to 12, wherein at least two semiconductor devices are fabricated in parallel by connecting two semiconductor dies to the first leadframe, providing two second leadframes, connecting each one of the two second leadframes with one of the semiconductor dies, applying two encapsulants to each one of the semiconductor dies and to first portions of the first and second leadframes, and singulating into two separate semiconductor devices.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A semiconductor device comprising
a first leadframe comprising a first die pad and one or more first leads formed integral with the first die pad and extending outward from the first die pad in a first direction;
a second leadframe comprising a second die pad and one or more second leads formed
integral with the second die pad and extending outward from the second die pad in a second direction different than the first direction;
a semiconductor die disposed between the first die pad and the second die pad; and
an encapsulant embedding the semiconductor die, wherein the first leads and the second leads are disposed outside the encapsulant;
characterized in that
the first die pad of the first leadframe is completely exposed at the top surface of the device.

2. The semiconductor device according to claim 1, wherein
the first die pad is disposed on a first level, and the second die pad is disposed on a second level, and
the first leads extend outside the encapsulant from the first level to a third level, and the second leads extend outside the encapsulant from the second level to the third level.

3. The semiconductor device according to claim 1, wherein
the semiconductor die is a vertical semiconductor transistor die, in particular a semiconductor power transistor die, an IGBT die, a MOSFET die, a CoolMOS die, a wide band gap semiconductor transistor die, in particular a SiC transistor die.

4. The semiconductor device according to claim 3, wherein
the semiconductor transistor die comprises a first main face and a second main face opposite to the first main face, and
a source pad disposed on the first main face and a drain pad disposed on the second main face.

5. The semiconductor device according to claim 4, wherein
the drain pad is connected with the first die pad of the leadframe and the source pad is connected with the second die pad of the second leadframe.

6. The semiconductor device according to claim 4, further comprising
a gate pad disposed on the first main face.

7. The semiconductor device according to claim 1, wherein
the device is a leaded package.

8. A method for fabricating a semiconductor device, the method comprising
providing a first leadframe comprising a first die pad and one or more first leads;
providing a semiconductor die comprising a first main face and a second main face opposite to the first main face;
connecting a first main face of the semiconductor die with a first portion of the first leadframe;
providing a second leadframe;
connecting a first portion of the second leadframe to the second main face of the semiconductor die;
applying an encapsulant to the semiconductor die and to the first portions of the first and second leadframes so that second portions of the first and second leadframes are disposed outside the encapsulant the first die pad of the first leadframe is completely exposed at the top surface of the device.

9. The method according to claim 8, further comprising
after applying the encapsulant bending at least part of the second portions of the first and second leadframes so that outer ends of the second portions come to lie in a plane which is parallel to the first portions of the first and second lead frames, or
providing one or both of the first and second leadframes in the form of pre-bent leadframes.

10. The method according to claim 9, wherein
the second portions of the first leadframe are bent by a first angle and the second portions of the second leadframe are bent by a second angle.

11. The method according to claim 8, wherein
the method is carried out such that a surface of the first portion of the first leadframe remote from the semiconductor die is exposed at the top surface of the package.

12. The method according to claim 8, wherein
at least two semiconductor devices are fabricated in parallel by
connecting two semiconductor dies to the first leadframe;
providing two second leadframes;
connecting each one of the two second leadframes with one of the semiconductor dies;
applying two encapsulants to each one of the semiconductor dies and to first portions of the first and second leadframes; and
singulating into two separate semiconductor devices.
